(19) United States
(12) Patent Application Publication
(10) Pub. No.: US 2025/0122622 A1
(43) Pub. Date: Apr. 17, 2025

(54) SHOWERHEAD DESIGN FOR PLASMA-ENHANCED DEPOSITION

(71) Applicant: Applied Materials, Inc., Santa Clara, CA (US)

(72) Inventors: Youngki Chang, Santa Clara, CA (US); Sanket S. Kurbet, Bangalore (IN); Dhritiman Subha Kashyap, Bangalore (IN); Tejas Umesh Ulav, Fremont, CA (US)

(73) Assignee: Applied Materials, Inc., Santa Clara, CA (US)

(21) Appl. No.: 18/379,915

(22) Filed: Oct. 13, 2023

(51) Int. Cl. C23C 16/455

(52) U.S. Cl. CPC C23C 16/45565

(57) ABSTRACT

Showerhead assemblies for semiconductor manufacturing processing chambers and semiconductor manufacturing processing chambers using the showerhead assemblies are described. The showerhead assemblies comprise a backing plate with an embedded heater and a faceplate. The embedded heater has a radius sufficient to located the heater over a sidewall of the processing chamber and reduces temperature non-uniformity of a wafer during processing.

### TECHNICAL FIELD

Embodiments of the disclosure are directed to showerheads for semiconductor manufacturing processing chambers. In particular, embodiments of the disclosure are directed to showerhead designs for the plasma-enhanced deposition of molybdenum films.

### BACKGROUND

Reliably producing submicron and smaller features is one of the key requirements of very large scale integration (VLSI) and ultra large scale integration (ULSI) of semiconductor devices. However, with the continued miniaturization of circuit technology, the dimensions of the size and pitch of circuit features, such as interconnects, have placed additional demands on processing capabilities. The various semiconductor components (e.g., interconnects, vias, capacitors, transistors) require precise placement of high aspect ratio features. Reliable formation of these components is critical to further increases in device and density.

Additionally, the electronic device industry and the semiconductor industry continue to strive for larger production yields while increasing the uniformity of layers deposited on substrates having increasingly larger surface areas. These same factors in combination with new materials also provide higher integration of circuits per unit area on the substrate.

As the dimensions of devices continue to shrink, so does the gap/space between the devices, increasing the difficulty to physically isolate the devices from one another. Filling in the high aspect ratio trenches/spaces/gaps between devices which are often irregularly shaped with high-quality dielectric materials is becoming an increasing challenge to implementation with existing methods including gap fill, hardmasks and spacer applications.

Molybdenum and molybdenum based films have attractive material and conductive properties. These films have been proposed and tested for applications from front end to back end parts of semiconductor and microelectronic devices. The Plasma-Enhanced Atomic Layer Deposition (PEALD) of molybdenum requires high uniformity, medium to high temperature for seamless uniform gapfill with adequate throughput. These requirements can be difficult to achieve with existing processing chamber hardware and showerhead designs.

Accordingly, there is a need in the art for improved showerheads and processing chambers for plasma-enhanced deposition of films.

### SUMMARY

One or more embodiments of the disclosure are directed to showerhead assemblies for semiconductor manufacturing processing chambers. The showerhead assemblies comprise a backing plate, a heater and a faceplate. The backing plate has a front surface and a back surface defining a thickness of the backing plate. An inlet opening is in a center of the backing plate extending through the thickness thereof. The backing plate has an outer portion and an inner portion, the front surface of the inner portion having a concave shape. The heater is embedded within the thickness of the backing plate. The heater has a circular shape with a radius measured from a center axis of the backing plate. The heater has a radius greater than a radius of the inner portion of the backing plate so that the heater is within the outer portion of the backing plate. The faceplate has a front surface and a back surface defining a thickness of the faceplate. The faceplate has an inner portion and an outer portion. A plurality of apertures extend through the thickness of the faceplate in the inner portion. A plurality of angled openings extend through the thickness of the outer portion of the faceplate. The plurality of angled openings have a front surface opening centered at a radius from a center axis of the faceplate greater than a back surface opening centered radius.

Additional embodiments of the disclosure are directed to semiconductor manufacturing processing chambers comprising a showerhead assembly as described herein. An inlet flange is connected to the back surface of the backing plate. The inlet flange has an inner channel aligned with the opening in the center of the backing plate. The inner channel has an upper portion and a lower portion. The upper portion has a larger inner diameter than an inner diameter of the lower portion. The processing chambers comprise a chamber sidewall and chamber bottom. The showerhead assembly is positioned to that the bottom surface of the pumping ring is in contact with a top surface of the chamber sidewall, forming an interior of the processing chamber. A substrate support is within the interior of the processing chamber. The substrate support has a support surface configured to support a wafer during processing. The support surface is spaced form the front surface of the faceplate to form a process gap.

Further embodiments of the disclosure are directed to showerhead assemblies for semiconductor manufacturing processing chambers. The showerhead assemblies comprise a backing plate, a faceplate and a pumping ring. The backing plate has a heater embedded within a thickness thereof. An inlet opening in a center of the backing plate extends through the thickness thereof. An inner portion of a front surface of the backing plate has a concave shape. The heater has a radius greater than a radius of the inner portion of the front surface. The faceplate has a plurality of apertures extending through a thickness of the faceplate at an inner portion of the faceplate. A plurality of angled openings extend through the thickness of the faceplate at an outer portion of the faceplate. The pumping ring is connected to the backing plate with a plurality of fasteners that extend through the faceplate.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 shows a cross-sectional schematic view of a processing chamber in accordance with one or more embodiment of the disclosure;

FIG. 2 shows an expanded view of the backing plate of the processing chamber shown in FIG. 1;

FIG. 3 illustrates an exploded view of region III of FIG. 2;

FIG. 4 illustrates an exploded view of a portion of the processing chamber of FIG. 1;

FIG. 5 illustrates a partial view of the faceplate of the processing chamber of FIG. 1;

FIG. 6 shows an expanded view of region VI of FIG. 1;

FIG. 7 illustrates a schematic view of a multi-station processing chamber comprises more than one semiconductor manufacturing processing chambers according to one or more embodiment of the disclosure; and

FIG. 8A shows an isometric view of a pumping ring according to one or more embodiment of the disclosure;

FIG. 8B shows a top plan view of the pumping ring of FIG. 8A;

FIG. 9A shows a top plan view of a choke plate according to one or more embodiment of the disclosure; and

FIG. 9B shows a bottom plan view of a choke plate according to one or more embodiment of the disclosure.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

As used in this specification and the appended claims, the term “substrate” refers to a surface, or portion of a surface, upon which a process acts. It will also be understood by those skilled in the art that reference to a substrate can also refer to only a portion of the substrate, unless the context clearly indicates otherwise. Additionally, reference to depositing on a substrate can mean both a bare substrate and a substrate with one or more films or features deposited or formed thereon.

A “substrate” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, amorphous silicon, doped silicon, germanium, gallium arsenide, glass, sapphire, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate, anneal, UV cure, e-beam cure and/or bake the substrate surface. In addition to film processing directly on the surface of the substrate itself, in the present disclosure, any of the film processing steps disclosed may also be performed on an underlayer formed on the substrate as disclosed in more detail below, and the term “substrate surface” is intended to include such underlayer as the context indicates. Thus, for example, where a film/layer or partial film/layer has been deposited onto a substrate surface, the exposed surface of the newly deposited film/layer becomes the substrate surface.

“Atomic layer deposition” or “cyclical deposition” as used herein refers to a process comprising the sequential exposure of two or more reactive compounds to deposit a layer of material on a substrate surface. “Atomic layer deposition” or “cyclical deposition” as used herein refers to a process comprising the sequential exposure of two or more reactive compounds to deposit a layer of material on a substrate surface. The substrate, or portion of the substrate, is exposed separately to the two or more reactive compounds which are introduced into a reaction zone of a processing chamber. In a time-domain ALD process, exposure to each reactive compound is separated by a time delay to allow each compound to adhere and/or react on the substrate surface and then be purged from the processing chamber. These reactive compounds are said to be exposed to the substrate sequentially. In a spatial ALD process, different portions of the substrate surface, or material on the substrate surface, are exposed simultaneously to the two or more reactive compounds so that any given point on the substrate is substantially not exposed to more than one reactive compound simultaneously. As used in this specification and the appended claims, the term “substantially” used in this respect means, as will be understood by those skilled in the art, that there is the possibility that a small portion of the substrate may be exposed to multiple reactive gases simultaneously due to diffusion, and that the simultaneous exposure is unintended.

In one aspect of a time-domain ALD process, a first reactive gas (i.e., a first precursor or compound A) is pulsed into the reaction zone followed by a first time delay. Next, a second precursor or compound B is pulsed into the reaction zone followed by a second delay. During each time delay, a purge gas, such as argon, is introduced into the processing chamber to purge the reaction zone or otherwise remove any residual reactive compound or reaction by-products from the reaction zone. Alternatively, the purge gas may flow continuously throughout the deposition process so that only the purge gas flows during the time delay between pulses of reactive compounds. The reactive compounds are alternatively pulsed until a desired film or film thickness is formed on the substrate surface. In either scenario, the ALD process of pulsing compound A, purge gas, compound B and purge gas is a cycle. A cycle can start with either compound A or compound B and continue the respective order of the cycle until achieving a film with the predetermined thickness.

In an embodiment of a spatial ALD process, a first reactive gas and second reactive gas (e.g., nitrogen gas) are delivered simultaneously to the reaction zone but are separated by an inert gas curtain and/or a vacuum curtain. The substrate is moved relative to the gas delivery apparatus so that any given point on the substrate is exposed to the first reactive gas and the second reactive gas. The gas curtain can be any suitable gas separation arrangement known to the skilled artisan. For example, in some embodiments of a spatial ALD process chamber, a gas curtain is formed by a combination of purge gas ports and vacuum ports to maintain separation between the reactive gases to prevent gas-phase reactions. In some embodiments of a spatial ALD process chamber, separate process stations are configured to form a mini-process environment within each station.

As used in this specification and the appended claims, the terms “reactive compound”, “reactive gas”, “reactive species”, “precursor”, “process gas” and the like are used interchangeably to mean a substance with a species capable of reacting with the substrate surface or material on the substrate surface in a surface reaction (e.g., chemisorption, oxidation, reduction, cycloaddition). The substrate, or portion of the substrate, is exposed sequentially to the two or more reactive compounds which are introduced into a reaction zone of a processing chamber.

Embodiments of the disclosure provide process chambers and showerheads for process chambers that enable the plasma-enhanced gapfill of molybdenum using existing station architecture with minimal design changes and decreased costs.

Some embodiments of the showerhead design enable new precursor delivery for conductively coupled plasma (CCP) molybdenum process. Improvements over existing designs include, but are not limited to, the incorporation of non-symmetric showerhead contacts, thinner gas box design and simplified embedded tubular heater for thermal uniformity and design simplification/cost reduction. As used herein, the terms “gas box” and “backing plate” are used interchangeably, as will be understood by the skilled artisan. A coated gas box plenum (also referred to as a showerhead plenum or showerhead assembly plenum) is used for chemical compatibility and elimination of the upper lid of the chamber for cost reduction.

Embodiments of the disclosure include an embedded tubular heater versus the previous machined component which holds a tubular heater with graphite sheet for contact. Some embodiments incorporate a thinner gas box (backing plate) by eliminating the need for cooling channels. Some embodiments adjust gas flow through the length of the gas manifold.

Some embodiments include a non-symmetrical minimum contact between the pumping ring and the showerhead faceplate to create a separation from the chamber body, which acts as a heat sink.

Some embodiments include a coated gas box plenum and/or coated faceplate for chemistry compatibility. Some embodiments provide increased emissivity to aid in the heating of the gas box and/or faceplate. In some embodiments, the gas box plenum has a coating with an emissivity in the range of 0.8-0.9.

Some embodiments provide for chlorine compatibility and moisture permeation improvements. Some embodiments eliminate the need for isolation valves for each station of a multi-station processing chamber through continuous inert gas purge to prevent back streaming from the remote plasma source (RPS).

In an exemplary four station chamber, edge temperature uniformity is lower than the center due to conductive heat transfer from the showerhead to the chamber through the pumping liner. To mitigate thermal non-uniformity, minimum contact is applied on the pumping liner to minimize conductive heat transfer from the showerhead to the pumping liner. The minimum contact of some embodiments means that the contact area at the edge has a gap greater than 0.1 mm, 0.15 mm, 0.2 mm, 0.25 mm or 0.3 mm.

In some embodiments, the process chamber has the heating coil location moved to the gas box (backing plate). The faceplate edge temperature and wafer edge temperature is usually lower than the center due to heat loss at the edge. For example, heat loss occurs due to the contact with the chamber wall which acts as a heat sink. To mitigate thermal non-uniformity, in some embodiments, the coil heater is applied at the gas box (backing plate) with a radius of about 150 mm.

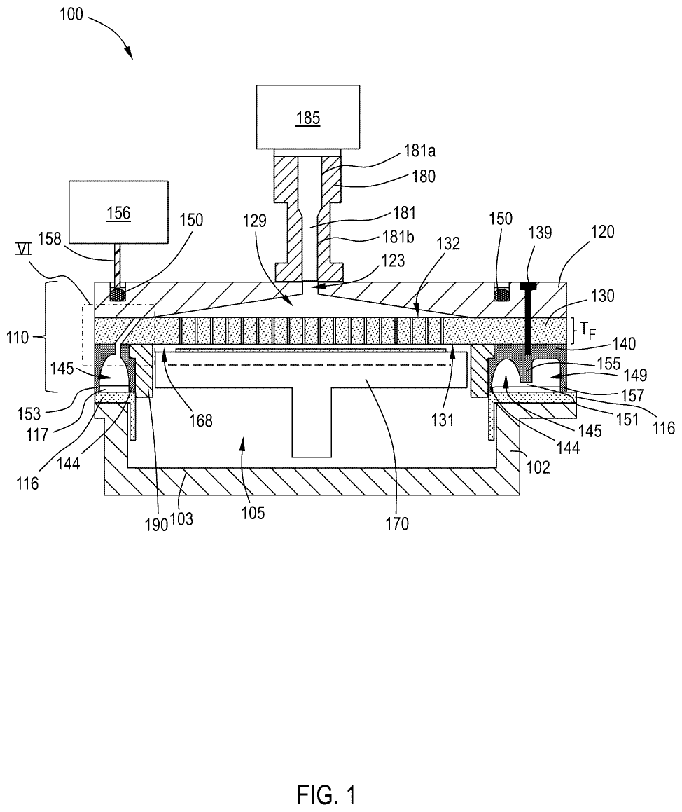

With reference to FIG. 1, one or more embodiments of the disclosure are directed to semiconductor manufacturing processing chambers 100 including a showerhead assembly 110. The showerhead assembly 110 comprises a backing plate 120 and a faceplate 130. In some embodiments, the showerhead assembly 110 further comprises a pumping ring 140. The showerhead assembly 110 illustrated in FIG. 1 includes the backing plate 120, faceplate 130 and pumping ring 140. However, the skilled artisan will recognize that the pumping ring 140 can be separate from the showerhead assembly 110 or, in some embodiments, can be omitted from the semiconductor manufacturing processing chamber 100.

The semiconductor manufacturing processing chambers 100 comprises a chamber body 101 with a sidewall 102 and bottom wall 103. The chamber body 101, in conjunction with the showerhead assembly 110 encloses an interior 105 of the semiconductor manufacturing processing chambers 100. The sidewall 102 and bottom wall 103 can be integrally formed or separate component connected together by any suitable connection or fastener known to the skilled artisan. During processing, the interior 105 of the semiconductor manufacturing processing chambers 100 is typically maintained at a controlled pressure (usually a low pressure environment) using one or more gas inlet (not shown) and one or more exhaust (not shown). The skilled artisan will be familiar with the general construction of a chamber body 101 and the use of gas inlets and exhaust systems.

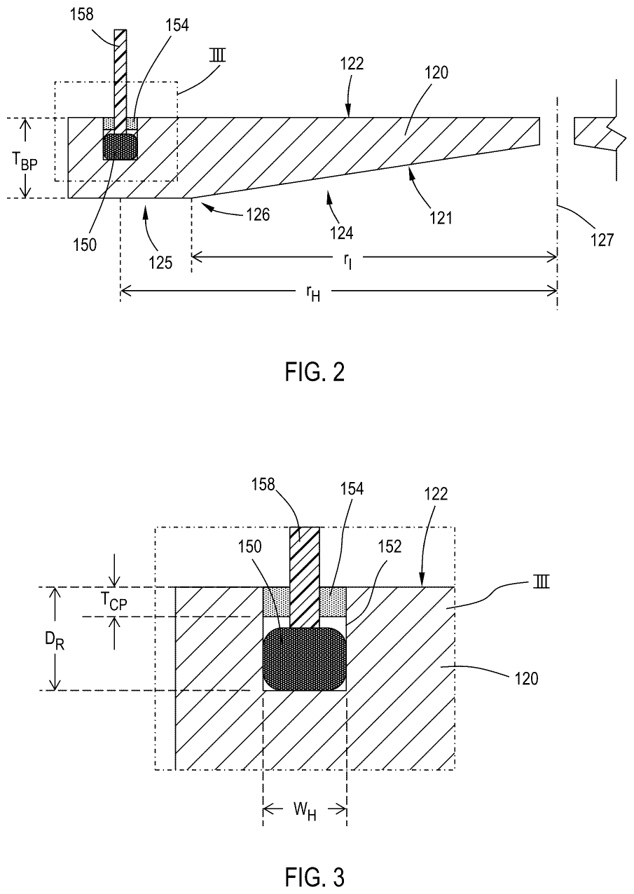

FIG. 2 shows an expanded view of a portion of the backing plate 120 shown in FIG. 1. FIG. 3 illustrates an exploded view of region III of FIG. 2. With reference to FIGS. 1-3, one or more embodiments of the disclosure are directed to a backing plate 120 for a showerhead assembly 110. The backing plate 120 has a front surface 121 and a back surface 122 that define a thickness T_{BP} of the backing plate 120.

The backing plate 120 has an inner portion 124 and an outer portion 125. The backing plate 120 contacts the faceplate 130 at the outer portion outer portion 125. The front surface 121 of the backing plate 120 at the inner portion 124 has a concave shape. The concave shape of some embodiments has a linear slope from the inlet opening 123 to the outer peripheral edge 126 of the inner portion 124, as illustrated in the Figures. In some embodiments, the concave shape is curved from the inlet opening 123 to the outer peripheral edge 126 of the inner portion 124.

The backing plate 120 has an inlet opening 123 in a center thereof. The inlet opening 123 extends through the thickness of the backing plate 120 from the back surface 122 to the front surface 121. The central axis 127 of the backing plate 120 is defined as the center of the inlet opening 123. The outer peripheral edge 126 of the inner portion 124 of the front surface 121 of some embodiments is concentric with the inlet opening 123. While the backing plate 120 of some embodiments has an oblong or non-symmetrical shape, the central axis 127 remains at the center of the inlet opening 123 even if that is not the center of mass of the backing plate 120.

The thickness T_{BP} of the backing plate 120 is measured at the outer peripheral edge of the backing plate 120. Stated differently, the thickness T_{BP} of the backing plate 120 is measured at the outer portion 125 of the front surface 121 of the backing plate 120 relative to the back surface 122 of the backing plate 120. In some embodiments, the thickness T_{BP} of the backing plate 120 is in the range of 0.5 inch to 1.5 inch, or about 1 inch.

A heater 150 is embedded within a thickness T_{BP} of the backing plate 120. The heater 150 of some embodiments is positioned within a recess 152 formed in the back surface 122 of the backing plate 120. The recess 152 of some embodiments has a depth DR, measured from the back surface 122 of the backing plate 120 that is at least the thickness of the heater 150. In some embodiments, the depth DR of the recess 152 is in the range of 20% to 80%, or 30% to 70%, or 50% to 60% of the thickness T_{BP} of the backing plate 120.

The heater 150 can be any suitable heating mechanism known to the skilled artisan. In some embodiments, the heater 150 comprises a resistive heating element. As used herein, the term “heater” is used interchangeably with “heating element”, “heater element” or “heating coil” and refers to the generally ring-shaped material that generates heat upon application of sufficient power from a power source 156 through any suitable electrical connection line 158.

The radius r_{H} of the heater 150 is measured from the central axis 127 of the backing plate 120 to the center of the width W_{H} of the heating element, as shown in FIG. 2. The width W_{H} of the heating element of the heater 150 of some embodiments is in the range of 1 mm to 15 mm, or in the range of 4 mm to 12 mm, or in the range of 6 mm to 10 mm.

In some embodiments, heater 150 has a radius r_{H} greater than a radius n of the inner portion 124 of the front surface 121 of the backing plate 120. In some embodiments, the heater 150 has a radius r_{H} greater than a radius n of the inner portion 125 of the front surface 121 of the backing plate 120 so that the heater 150 is within the outer portion 125 of the backing plate 120. Stated differently, in some embodiments, the heater 150 has a radius r greater than the radius n of the inner portion 125 of the front surface front surface 121 of the backing plate 120 plus half the width W_{H} of the heater 150.

To mitigate thermal non-uniformity, in some embodiments, the coil heater is applied at the gas box with a radius of about 150 mm. In some embodiments, the heater 150 has a radius r_{H} of about 150 mm so that the center of the heater 150 is positioned over the edge of a 300 mm wafer positioned on a substrate support within the processing chamber. In some embodiments, the heater 150 has a radius r_{H} greater than or equal to 150 mm, 155 mm, 160 mm, 165 mm, 170 mm, 175 mm, 180 mm, 185 mm, 190 mm, 195 mm, 200 mm, 202.5 mm, 205 mm, 207.5 mm, 210 mm, 212.5 mm, 215 mm or 220 mm. Stated differently, in some embodiments, the heater 150 has a centerline diameter greater than or equal to 380 mm, 390 mm, 395 mm, 400 mm, 405 mm, 410 mm, 415 mm, 420 mm, 425 mm, 430 mm, 435 mm or 440 mm. The heater 150 of some embodiments has a radius r_{H} less than 250 mm, 240 mm or 230 mm. In some embodiments, the radius r_{H} is in the range of 150 mm to 250 mm, or in the range of 160 mm to 240 mm, or in the range of 175 mm to 235 mm.

In some embodiments, as shown in the Figures, the heater 150 is positioned in a heater recess 152 formed in the back surface 122 of the backing plate 120, and the heater 150 is covered in the heater recess 152 by a heater cover plate 154. The heater cover plate 154 of some embodiments has a thickness T_{CP} in the range of 1 mm to 10 mm, or in the range of 2 mm to 5 mm, or about 3 mm. The heater cover plate 154 of some embodiments is friction fit into the recess 152. In some embodiments, the heater cover plate 154 is permanently affixed to the recess 152 (e.g., welded, fastened). In some embodiments, the heater element is located at a diameter in the range of 400 mm to 440 mm, centered around the opening 123.

Including the heater 150 in the back surface 122 of the backing plate 120 allows for reduced thickness of the backing plate 120. Typically, additional lid components are included with the processing chamber so that cooling channels are embedded within the backing plate 120. By moving the heater 150 to be embedded in the backing plate 120 at the outer portion, the cooling channels can be omitted, reducing the overall thickness of the backing plate 120 and eliminating the need for the additional lid components.

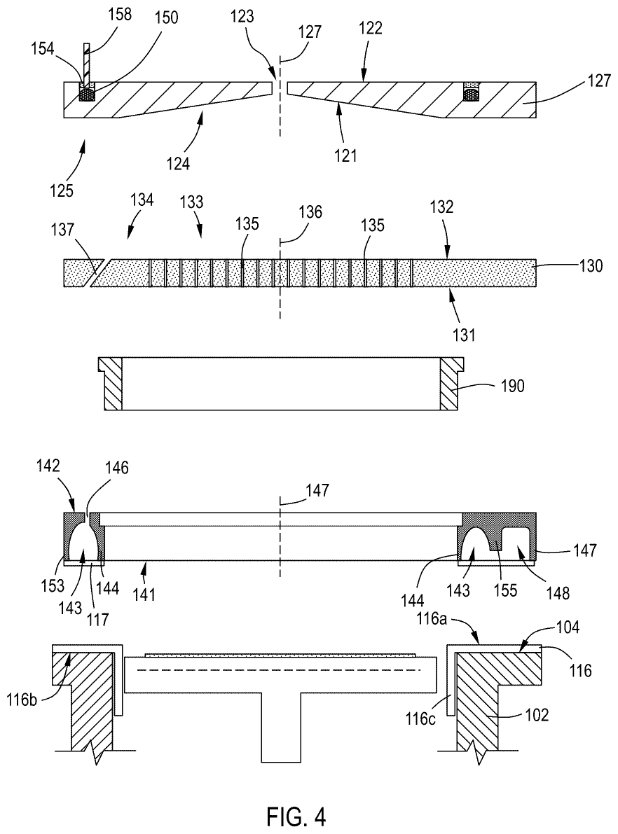

FIG. 4 illustrates a portion of the processing chamber 100 of FIG. 1 exploded to illustrate the components. Referring to FIGS. 1 and 4, the showerhead assembly 110 includes a faceplate 130, which may also be referred to as a “showerhead”. The faceplate 130 has a front surface 131 and a back surface 132 defining a thickness T_{F} of the faceplate 130. In some embodiments, the thickness T_{F} of the faceplate 130 is about 1 inch.

The faceplate 130 has an inner portion 133 and an outer portion 134. The inner portion 133 of the faceplate 130 aligns with the inner portion 124 of the backing plate 120 and the outer portion 134 of the faceplate 130 aligns with the outer portion 125 of the backing plate 120. The inner portion 133 of the faceplate 130 comprises a plurality of apertures 135 extending through the thickness T_{F} of the faceplate 130.

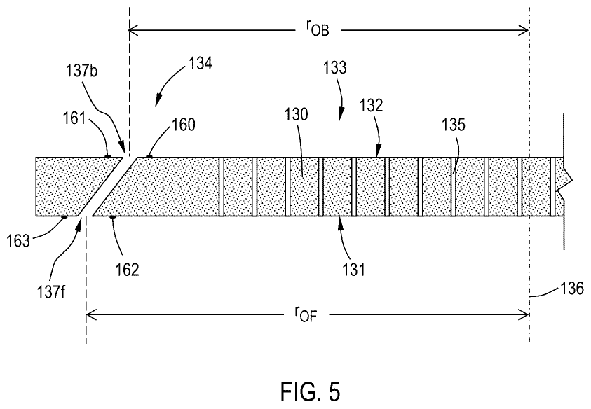

FIG. 5 illustrates a partial view of the faceplate 130 of FIG. 1. In some embodiments, a plurality of angled openings 137 extend through the thickness of the outer portion 134 of the faceplate 130.

The plurality of angled openings 137 are angled inwardly from the front surface 131 to the back surface 132 of the faceplate 130. Stated differently, the plurality of angled openings 137 have a front surface opening 137f centered at a radius r_{OF} from a center axis 136 of the faceplate 130 that is larger than a back surface opening 137b centered at a radius R_{OB} from the center axis 136. The center axis 136 of the faceplate 130 is coaxial with the central axis 127 of the backing plate 120. In some embodiments, the diameter of the backing plate is in the range of 300 mm to 320 mm, or about 310 mm.

In some embodiments, the plurality of angled openings 137 have an angle relative to the front surface 131 of the faceplate 130 in the range of 75° to 15°, or in the range of 60° to 30°, or in the range of 50° to 40°.

Referring to FIG. 1, the backing plate 120 can be connected to the faceplate 130 by any suitable mechanism known to the skilled artisan. For example, the backing plate 120 can be welded to the faceplate 130. In some embodiments, as shown in FIG. 1, the backing plate 120 is connected to the faceplate 130 with a plurality of fasteners 139. Suitable fasteners include, but are not limited to, bolts.

When the front surface 121 of the outer portion 125 of the backing plate 120 is in contact with the outer portion 134 of the back surface 132 of the faceplate 130, a gas box plenum 129 is formed in the space between the front surface 121 of the inner portion 124 of the backing plate 120 and the inner portion 133 of the back surface 132 of the faceplate 130.

In some embodiments, the gas box plenum 129 has a coating to improve chemical compatibility. In some embodiments, the coating covers the entire front surface 121 of the backing plate 120 and the entire back surface 132 of the faceplate 130, including in the inlet opening 123 of the backing plate 120 and the plurality of apertures 135 of the faceplate 130. In some embodiments, the coating is only on the portions of the backing plate 120 and faceplate 130 that will come into contact with the process gases.

In some embodiments, one or more of the backing plate 120 or faceplate 130 comprises a material with increased emissivity, aiding in the heating of the backing plate 120 or faceplate 130. In some embodiments, one or more of the backing plate 120 or faceplate 130 have a coating that increases the emissivity. In some embodiments, the emissivity of the coated gas box plenum 129 is increased, aiding the heating of the gas box (backing plate 120) and/or faceplate 130.

Some embodiments provide for chlorine compatibility and moisture permeation improvements. Without being bound by any particular theory of operation, it is believed that the dual seal and differential pumping of the volume between O-rings increases the chloring compatibility and moisture permeation of the system.

Some embodiments of the showerhead assembly 110 further comprise a pumping ring 140. Referring to FIGS. 1 and 4, the pumping ring 140 has a front surface 141 and a back surface 142 defining a thickness of the pumping ring 140. In use, the back surface 142 of the pumping ring 140 is positioned adjacent to or in contact with the front surface 131 of the faceplate 130.

In some embodiments, the pumping ring 140 is connected to the backing plate 120 with a plurality of fasteners 139 that extend through the faceplate 130, as shown in FIG. 1. In some embodiments, bolting the backing plate 120 to the pumping ring 140 sandwiches the faceplate 130 between the backing plate 120 and the pumping ring 140.

In some embodiments, the pumping ring 140 has a recess 143 in the front surface 141 to form a pumping volume when the front surface 141 of the pumping ring 140 is adjacent another surface. For example, as shown in FIG. 1, when the pumping ring 140 is positioned so that the front surface 141 is adjacent to or in contact with the chamber sidewall 102 (or pumping ring cover 117 or choke plate 116), a pumping volume 145 is formed. In some embodiments, the pumping ring 140 includes a pumping ring cover 117 which when in contact with the pumping ring 140 forms the pumping volume 145. The pumping ring cover 117 can be a separate component on the sidewall 102 of the chamber or can be a separate component between the pumping ring 140 and the sidewall 102 or choke plate 116. In the embodiment illustrated in FIG. 1, the front surface 141 of the pumping ring 140 is shown in contact with the choke plate 116 with the pumping ring liner 117 between. In some embodiments, the pumping ring liner 117 is between the front surface 141 of the pumping ring 140 and the choke plate 116, as shown in FIG. 4.

At least one aperture 146 extends between the recess 143 in the front surface 141 of the pumping ring 140 and the back surface 142 of the pumping ring 140. The at least one aperture 146 has a radius equal to a radius of the front surface opening 137f of the angled openings 137 in the faceplate 130.

It has been surprisingly found that locating the heating coil (heater 150) at the edge of the inner portion 124 of the backing plate 120 reduces the faceplate 130 temperature non-uniformity by at least 25%, 30%, 35%, 36% or 40%. In some embodiments, the minimum contact design between the pumping liner 140 and the faceplate 130 reduces the showerhead temperature non-uniformity by at least 10%, 15%, 18%, 20% or 25%. In a conventional processing chamber, with normal contact area between the showerhead and the pumping ring, the temperature non-uniformity on the faceplate, measured center to edge, is greater than 5.5° C. or 6° C. In some embodiments, the temperature non-uniformity on the faceplate 130 is less than or equal to 5° C., 4° C., 3.5° C., 3.25° C., 3° C., 2.5° C. or 2.3° C. when the faceplate 130 is set at 150° C.

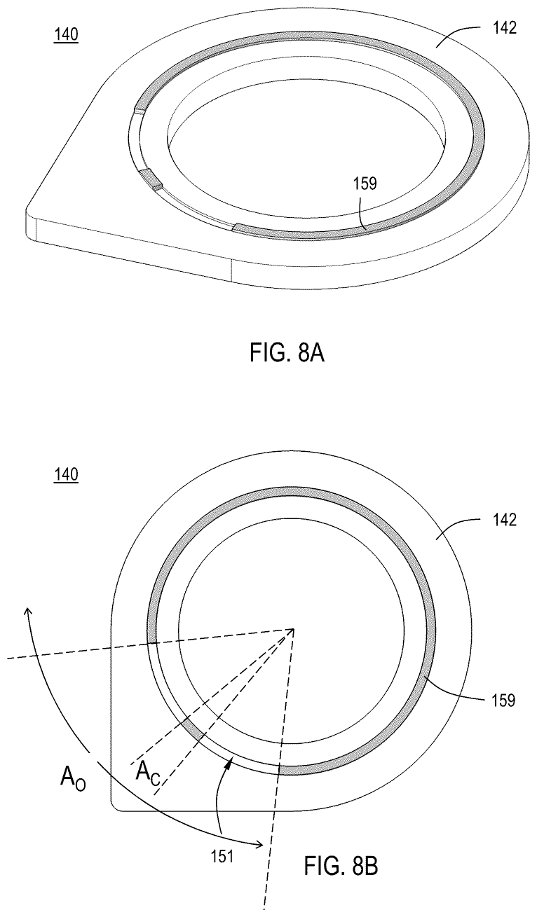

In some embodiments, the pumping ring 140 has a non-symmetrical shape. For example, as shown in the Figures, one side or portion of the pumping ring 140 extends further from the central axis 147 of the pumping ring 140. As shown in FIG. 4, the right side of the pumping ring 140 extends further from the central axis 147 than the left side of the pumping ring 140. The embodiment illustrated in FIGS. 8A and 8B has the left side of the pumping ring 140 extending further from the central axis 147. This can be, for example, to accommodate an exhaust recess 148 (see FIG. 4) which, when the pumping ring 140 is positioned on the sidewall 102 of the processing chamber body 101, creates an exhaust plenum 149. The exhaust plenum 149 is connected to the pumping volume 145 by one or more exhaust channels 151. The exhaust channels 151 of some embodiments are formed as one or more recess or cutout in the front surface 141 of the pumping ring 140 connecting the recess 143 with the exhaust recess 148. In some embodiments, the exhaust channels 151 are separated from the exhaust plenum 149 by a truncated wall 155 of the pumping ring 140. FIG. 8 shows a bottom view of the pumping ring 140 according to one or more embodiments of the disclosure. In this embodiment, only the front surface 141 is illustrated to show the contact points with the top surface 104 of the sidewall 102. The inner wall 144 of the pumping ring 140 is illustrated as a continuous annulus while the outer wall 153 is asymmetrical. The outer wall 153 extends to enclose the exhaust plenum 149 and the depth of the outer wall 153 transitions to a truncated wall 155 to form the one or more exhaust channels 151. The shape of the pumping ring 140 illustrated in the Figures is merely representative of one possible configuration for descriptive purposes and should not be taken as limiting the scope of the disclosure. In some embodiments, the shape of the pumping ring 140 allows for symmetrical or asymmetrical placement of multiple exhaust recesses 148 around the periphery of the pumping ring 140.

The cutouts in the front surface 141 of the pumping ring 140 allow for minimum contact with the sidewall 102 of the chamber body 101 which acts as a heat sink during processing. The inventors have surprisingly found that the non-symmetrical minimum contact between the pumping ring 140 and the heat sink creates sufficient separation to the faceplate 130 to reduce the temperature non-uniformity of the faceplate 130 during processing. The sidewall 102 of the chamber body may include a choke plate 116. The choke plate 116 of some embodiments is a separate component that fits within the chamber body and is at least partially supported by or in contact with the sidewall 102 of the chamber body 101. In some embodiments, the minimum contact described herein is maintained between the pumping ring 140 and the choke plate 116 in addition to between the pumping ring 140 and the faceplate 130.

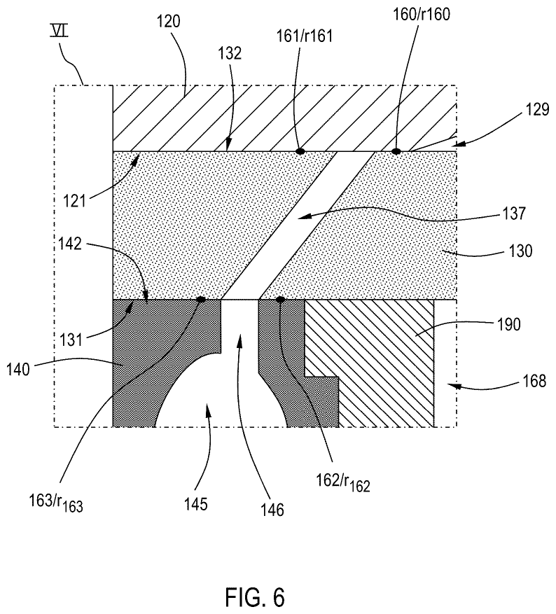

During use, the backing plate 120, faceplate 130 and pumping ring 140, in addition to other components, may be separated by one or more O-rings to help maintain a fluid-tight seal for the processing chamber. FIG. 6 shows an expanded view of region VI of FIG. 1 showing the showerhead assembly 110. In some embodiments, the showerhead assembly 110 includes a plurality of O-rings positioned between the backing plate 120 and the faceplate 130 and/or a plurality of O-rings positioned between the faceplate 130 and the pumping ring 140.

In some embodiments, the showerhead assembly 110 includes an inner backing plate O-ring 160 between the backing plate 120 and the faceplate 130. The inner backing plate O-ring 160 has a radius r₁₆₀ greater than or equal to a radius of the inner portion n of the front surface 121 of the backing plate 120.

In some embodiments, the showerhead assembly 110 includes an outer backing plate O-ring 161 between the backing plate 120 and the faceplate 130. The outer backing plate O-ring 161 has a radius r₁₆₁ greater than the radius r₁₆₀ of the inner backing plate O-ring 160. The radius r₁₆₀ of the inner backing plate O-ring 160 is smaller than radius r_{OB} of the back surface opening 137b of the angled openings 137 in the faceplate 130. The radius r₁₆₁ of the outer backing plate O-ring 161 is greater than the radius r_{OB} of the back surface opening 137b of the angled openings 137 in the faceplate 130.

Some embodiments of the showerhead assembly 110 include an inner pumping ring O-ring 162 and/or an outer pumping ring O-ring 163. The inner pumping ring O-ring 162 has a radius r₁₆₂ smaller than radius r_{OF} of the front surface openings 137f of the angled openings 137 in the faceplate 130. In some embodiments, the outer pumping ring O-ring 163 has a radius r₁₆₃ greater than the radius r_{OF} of the front surface openings 137f of the angled openings 137 in the faceplate 130.

Referring again to FIGS. 1 and 4, some embodiments of the disclosure are directed to semiconductor manufacturing processing chambers 100 comprising the showerhead assembly 110 described herein.

A substrate support 170 is located within the interior 105 of the semiconductor manufacturing processing chamber 100. The substrate support 170 of some embodiments comprises a support body 171 positioned on a support shaft 172. The support body 171 has a support surface 173 configured to support a semiconductor wafer 108 for processing. The support shaft 172 of some embodiments is configured to move the support body 171 closer to/further from the faceplate 130 and/or around a rotational axis of the support shaft 172. During processing, the support surface 173 is spaced from the front surface 131 of the faceplate 130 to form a process gap 168.

In some embodiments, the support body 171 includes a thermal element 174 configured to heat the semiconductor wafer 108 on the support surface 173. The thermal element 174 can be any suitable heating mechanism known to the skilled artisan. For example, in some embodiments, the thermal element 174 comprises a resistive heating element that is connected to a power supply (not shown) configured to apply power to the thermal element 174 to heat the support body 171. In some embodiments, the support body 171 includes an electrostatic chuck (ESC) (not shown). The skilled artisan will be familiar with the construction of the ESC and the manner in which the ESC is powered and employed.

In some embodiments, the semiconductor manufacturing processing chambers 100 further comprises an inlet flange 180 connected to the back surface 122 of the backing plate 120. The inlet flange 180 has an inner channel 181 aligned with the opening 123 in the center of the backing plate 120. The inner channel 181 of some embodiments has an upper portion 181a and a lower portion 181b. The upper portion 181a has a larger inner diameter than an inner diameter of the lower portion 181b.

In some embodiments, the showerhead assembly 110 is positioned to that the bottom surface 141 of the pumping ring 140 is in contact with a top surface 104 of the chamber sidewall 102, forming an interior 105 of the processing chamber 100. In some embodiments, the top surface 104 of the chamber sidewall 102 has a choke plate 116 positioned thereon with the pumping ring 140 in contact with the choke plate 116. In some embodiments, the heater 150 within the backing plate 120 is positioned so that the heater 150 is located over the top surface 104 of the sidewall 102. The skilled artisan will recognize that the pumping ring 140 can be in contact with the top surface 104 of the chamber sidewall 102 through the choke plate 116, or the pumping ring 140 can be in direct contact with the top surface 104 of the chamber sidewall 102. As used in this manner, “direct contact” means that the stated parts touch without an intervening component. In some embodiments, the pumping ring 140 is in direct contact with the choke plate 116 and the choke plate 116 is in direct contact with the top surface 104 of the chamber sidewall 102.

Some embodiments of the semiconductor manufacturing processing chamber 100 further comprise a remote plasma source (RPS) 185 connected to the inlet flange 180. In use, a plasma generated in the remote plasma source 185 flows through the inlet flange 180 into the gas box plenum 129. In some embodiments, an inert gas purge line (not shown) is connected to the inner channel 181 of the inlet flange 180 to provide a continuous inert gas purge to prevent back streaming of gases to the remote plasma source 185. In some embodiments, the inert gas purge line is connected to the lower portion 181b of the inner channel 181 within 50 mm of the upper portion 181a of the inner channel 181. In some embodiments, inclusion of the inert gas purge eliminates the need for an isolation valve through continuous inert gas purge.

In some embodiments, as shown in FIGS. 1 and 4, the semiconductor manufacturing processing chambers 100 includes a RF shield 190. The RF shield 190 is a generally ring-shaped component that is positioned within the interior 105 of the semiconductor manufacturing processing chambers 100 between the substrate support 170 and the sidewall 102. The RF shield 190 helps to prevent reactive gases from flowing from the process gap 168 to the interior 105 of the chamber body 101. However, any reactive gases that do migrate from the process gap 168 to the interior 105 can be evacuated by the chamber vacuum line (not shown).

In the semiconductor manufacturing processing chambers 100 of some embodiments, the front surface 141 of the pumping ring 140 has minimal contact with the chamber sidewall 102 to minimize heat transfer between the faceplate 130 and the chamber sidewall 102. FIG. 8A shows an isometric view of a pumping ring 140 according to one or more embodiments of the disclosure. FIG. 8B shows a top plan view of the pumping ring 140 of FIG. 8A. In one or more embodiments, the exhaust region A_{O} of the pumping ring 140 takes up greater than or equal to 45°, 50°, 55°, 60°, 65°, 70° or 75° of the circle formed by the pumping ring 140. The exhaust region A_{O} is a portion of the pumping ring 140 adjacent to the chamber exhaust where exhaust plenum is formed. In some embodiments, a contact region A_{C} occurs within the exhaust region A_{O} of the pumping ring 140 for support purposes. In some embodiments, the contact region A_{C} occupies less than or equal to 20°, 15°, 10° or 5° of the circle formed by the pumping ring 140 within the exhaust region A_{O}. In some embodiments, the exhaust region A_{O} has an angular length occupying 60° of the circle formed by the pumping ring 140 and the contact region A_{C} occupies 10° of the circle formed by the pumping ring 140. In some embodiments, the exhaust contact portion and is located in about the center of the opening of the exhaust region A_{O} in the one or more exhaust channels 151. In a conventional system, the faceplate loses heat to the pumping ring due to contact between the parts, resulting in a faceplate temperature non-uniformity of about 4° C. In some embodiments of the disclosure, the minimal contact between the pumping ring and adjacent parts results in a non-uniformity of about 3.3° C., or lower. In some embodiments, the semiconductor manufacturing processing chamber 100 does not include an additional chamber lid to maintain temperature uniformity. In some embodiments, the decrease in thermal non-uniformity eliminates the need for an additional lid heater.

FIGS. 8A and 8B illustrate a top view of the pumping ring 140 according to some embodiments. In some embodiments, the bottom view of the pumping ring 140 is a mirror image of the top view so that the open region in the contact ring 159 is located in about the same portion of the pumping ring 140 on the top surface and bottom surface. In some embodiments, the contact ring 159 is a separate component inserted into a groove formed in the top surface and/or bottom surface of the pumping ring 140. In some embodiments, the contact ring 159 is integrally formed as a part of the pumping ring 140. In some embodiments, the contact ring 159 has a height, measured from the top surface 142 of the pumping ring 140 in the range of 0.1 mm to 0.5 mm, or in the range of 0.15 mm to 0.3 mm, or about 0.2 mm. In some embodiments, the contact ring 159 has a width in the range of 4 mm to 8 mm, or in the range of 5 mm to 7 mm, or about 6 mm.

In some embodiments, the minimum contact is formed between the pumping ring liner 117 and the pumping ring 140 and between the pumping ring liner 117 and the choke plate 116.

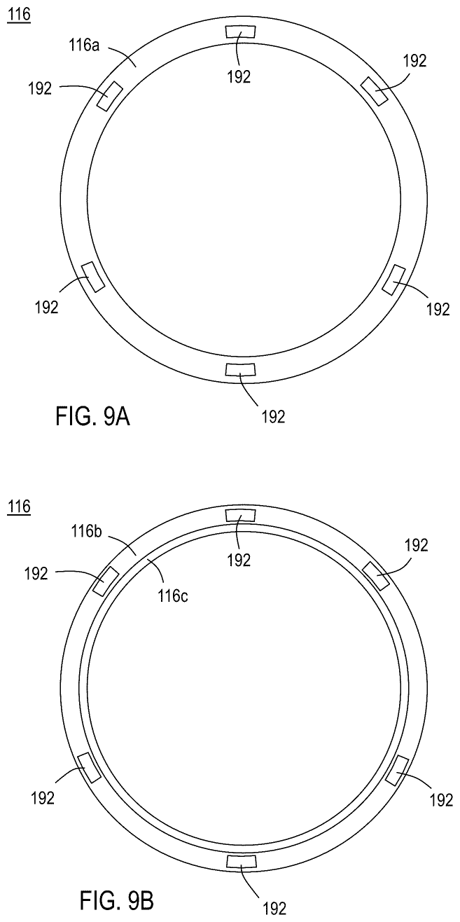

In some embodiments, as shown in FIG. 9A, the top surface 116a of the choke plate 116 includes a plurality of standoffs 192 arranged around the periphery of the choke plate 116. The standoffs 192 of some embodiments are small bumps formed in the surface of one or more of the components so that when positioned adjacent another component, the contact between the components is limited to the tops of the standoffs 192. FIG. 9B shows the bottom surface 116b and inner flange 116c of the choke plate 116. A plurality of standoffs 192 are shown on the bottom surface 116b of the choke plate 116 outside of the diameter of the inner flange 116c. While FIGS. 9A and 9B illustrate a ring-shaped choke plate 116, the skilled artisan will recognize that other shaped choke plates are within the scope of the disclosure.

There can be any suitable number of standoffs 192 depending on, for example, the size of the choke plate 116, and the material of construction. In the illustrated embodiments, there are six standoffs 192 on each of the top surface 116a and bottom surface 116b of the choke plate 116. In some embodiments, there are three, four, five, six, seven, eight, nine, 10, 11, 12 or more standoffs independently on the top surface 116a and the bottom surface 116b of the choke plate 116. The size of the standoffs 192 can be configured to maintain minimum contact between the adjacent components.

In some embodiments, the minimum contact is formed between the top surface of the choke plate 116 and the bottom surface of the pumping liner cover 117. In some embodiments, the minimum contact is formed between the bottom surface of the choke plate 116 and the top surface of the chamber wall 102. In some embodiments, the minimum contact is formed between the choke plate 116 and both the chamber wall 102 and the pumping liner cover 117 and/or pumping liner 140.

In an exemplary four station chamber, edge temperature uniformity is lower than the center due to conductive heat transfer from the showerhead to the chamber through the pumping liner. To mitigate thermal non-uniformity, minimum contact is applied on the pumping liner to minimize conductive heat transfer from the showerhead to the pumping liner. The minimum contact of some embodiments means that the contact area at the edge has a gap greater than 0.1 mm, 0.15 mm, 0.2 mm, 0.25 mm or 0.3 mm.

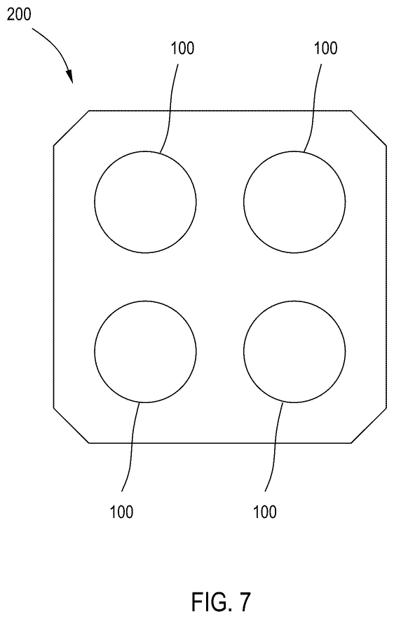

Some embodiments of the disclosure are directed to multi-station processing chambers. For example, as shown in FIG. 7, the multi-station processing chamber 200 comprises more than one semiconductor manufacturing processing chambers 100. In some embodiments, the multi-station processing chamber 200 comprises four stations. In some embodiments, the four stations create a thermal non-uniformity towards the pumping port at each station. The minimal contact results in a height or gap between the pumping ring and adjacent components in the range of 0.1 mm to 0.3 mm.

Embodiments of the disclosure provide process chambers and showerheads for process chambers that enable the plasma-enhanced gapfill of molybdenum using existing station architecture with minimal design changes and decreased costs. Embodiments of the disclosure improve the gapfill process by decreasing the size of the process gap, leading to faster cycle times, improved thermal uniformity and better plasma stability.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. Furthermore, the particular features, structures, materials, or characteristics may be combined in any suitable manner in one or more embodiments.

Although the disclosure herein has been described with reference to particular embodiments, those skilled in the art will understand that the embodiments described are merely illustrative of the principles and applications of the present disclosure. It will be apparent to those skilled in the art that various modifications and variations can be made to the method and apparatus of the present disclosure without departing from the spirit and scope of the disclosure. Thus, the present disclosure can include modifications and variations that are within the scope of the appended claims and their equivalents.

What is claimed is:

1. A showerhead assembly for a semiconductor manufacturing processing chamber, the showerhead assembly comprising:
a backing plate having a front surface and a back surface defining a thickness of the backing plate, an inlet opening in a center of the backing plate extending through the thickness thereof, the backing plate having an outer portion and an inner portion, the front surface of the inner portion having a concave shape;
a heater embedded within the thickness of the backing plate, the heater having a circular shape with a radius measured from a center axis of the backing plate, the heater having a radius greater than a radius of the inner portion of the backing plate so that the heater is within the outer portion of the backing plate; and
a faceplate having a front surface and a back surface defining a thickness of the faceplate, the faceplate having an inner portion and an outer portion, a plurality of apertures extending through the thickness of the faceplate in the inner portion, a plurality of angled openings extending through the thickness of the outer portion of the faceplate, the plurality of angled openings having a front surface opening centered at a radius from a center axis of the faceplate than a back surface opening centered radius.

2. The showerhead assembly of claim 1, wherein the heater has a radius in the range of 175 mm to 235 mm.

3. The showerhead assembly of claim 2, wherein the heater is positioned in a heater recess formed in the back surface of the backing plate, and the heater is covered in the heater recess by a heater cover plate.

4. The showerhead assembly of claim 1, wherein the backing plate is connected to the faceplate with a plurality of fasteners.

5. The showerhead assembly of claim 4, further comprising an inner backing plate O-ring between the backing plate and the faceplate, the inner backing plate O-ring having a radius greater than or equal to a radius of the inner portion of the front surface of the backing plate.

6. The showerhead assembly of claim 5, further comprising a pumping ring having a back surface and a front surface defining a thickness of the pumping ring, the back surface of the pumping ring adjacent to the front surface of the faceplate.

7. The showerhead assembly of claim 6, wherein the backing plate is bolted to the pumping ring with the faceplate sandwiched between the backing plate and the pumping ring.

8. The showerhead assembly of claim 7, further comprising:
an outer backing plate O-ring between the backing plate and the faceplate, the outer backing plate O-ring having a radius greater than the radius of the inner backing plate O-ring, the radius of the inner backing plate O-ring smaller than radius of the back surface opening of the angled openings in the faceplate, the radius of the outer backing plate O-ring greater than the radius of the back surface opening of the angled openings in the faceplate; and
an inner pumping ring O-ring and an outer pumping ring O-ring, the inner pumping ring O-ring having a radius smaller than radius of the front surface openings of the angled openings in the faceplate, the outer pumping ring O-ring having a radius greater than the radius of the front surface openings of the angled openings in the faceplate.

9. The showerhead assembly of claim 8, wherein the pumping ring has a recess in the bottom surface to form a pumping volume when the front surface of the pumping ring is adjacent another surface, and at least one aperture extending between the recess in the front surface of the pumping ring and the back surface of the pumping ring, the at least one aperture having a radius equal to a radius of the front surface opening of the angled openings in the faceplate.

10. A semiconductor manufacturing processing chamber comprising:
the showerhead assembly of claim 9;
an inlet flange connected to the back surface of the backing plate, the inlet flange having an inner channel aligned with the opening in the center of the backing plate, the inner channel having an upper portion and a lower portion, the upper portion having a larger inner diameter than an inner diameter of the lower portion;
a chamber sidewall and chamber bottom, the showerhead assembly positioned to that the bottom surface of the pumping ring is in contact with a top surface of the chamber sidewall, forming an interior of the processing chamber; and
a substrate support within the interior of the processing chamber, the substrate support having a support surface configured to support a wafer during processing, the support surface spaced from the front surface of the faceplate to form a process gap.

11. The semiconductor manufacturing processing chamber of claim 10, wherein the heater is located over the top surface of the chamber sidewall.

12. The semiconductor manufacturing processing chamber of claim 10, further comprising a remote plasma source (RPS) connected to the inlet flange.

13. The semiconductor manufacturing processing chamber of claim 10, wherein the bottom surface of the pumping ring has minimal contact with the chamber sidewall to minimize heat transfer between the faceplate and the chamber sidewall.

14. The semiconductor manufacturing processing chamber of claim 13, wherein no additional chamber lid is needed to maintain temperature uniformity.

15. The semiconductor manufacturing processing chamber of claim 14, wherein thermal non-uniformity of the faceplate is less than 3.5° C.

16. A showerhead assembly for a semiconductor manufacturing processing chamber, the showerhead assembly comprising:
a backing plate with a heater embedded within a thickness thereof, an inlet opening in a center of the backing plate extending through the thickness thereof, an inner portion of a front surface of the backing plate having a concave shape, the heater having a radius greater than a radius of the inner portion of the front surface;
a faceplate having a plurality of apertures extending through a thickness of the faceplate at an inner portion of the faceplate, and a plurality of angled openings extending through the thickness of the faceplate at an outer portion of the faceplate; and
a pumping ring connected to the backing plate with a plurality of fasteners that extend through the faceplate.

17. The showerhead assembly of claim 16, wherein the heater has a radius greater than 175 mm.

18. The showerhead assembly of claim 17, wherein the heater is positioned in a heater recess formed in the back surface of the backing plate, and the heater is covered in the heater recess by a heater cover plate.

19. The showerhead assembly of claim 18, further comprising a plurality of O-rings positioned between the backing plate and the faceplate and a plurality of O-rings positioned between the faceplate and the pumping ring.

20. A semiconductor manufacturing processing chamber comprising:
a chamber sidewall and chamber bottom;
the showerhead assembly of claim 19 positioned on the chamber sidewall to enclose an interior of the processing chamber, the heater positioned over the chamber sidewall.
